(19) United States
(12) Patent Application Publication
(10) Pub. No.: US 2022/0256743 A1
(43) Pub. Date: Aug. 11, 2022

(54) SIMPLIFIED LIQUID COOLED CARD CAGE WITH INTERNAL AND EXTERNAL HEAT

(71) Applicant: BAE SYSTEMS Information and Electronic Systems Integration Inc., Nashua, NH (US)

(72) Inventors: Gerard J. Pelletier, Amherst, NH (US); David E. Thompson, Nashua, NH (US)

(73) Assignee: BAE SYSTEMS Information and Electronic Systems Integration Inc., Nashua, NH (US)

(21) Appl. No.: 17/172,143

(22) Filed: Feb. 10, 2021

(51) Int. Cl. H05K 7/20

(52) U.S. Cl. CPC H05K 7/20636; H05K 7/20281

(57) ABSTRACT

The system and method for cooling a card cage using a compact combination vacuum/dip brazed card cage with integral liquid cooling passages, wherein all surfaces of the card cage are used for cooling. The card cage cooling 3U circuit cards internally and non-standard boards mounted externally by heat sinking the non-standard boards to the external walls. Finned, internal liquid cooling passages being orificed to maintain a total pressure drop from a single system inlet to a single system outlet of no more than 5 psi.

### STATEMENT OF GOVERNMENT INTEREST

This disclosure was made with United States Government support under a classified Contract No. awarded by a classified agency. The United States Government has certain rights in this disclosure.

### FIELD OF THE DISCLOSURE

The present disclosure relates to card cages and more particularly to a liquid cooled card cage for addressing internal and external heat sources for use with 3U printed circuit cards, and the like.

### BACKGROUND OF THE DISCLOSURE

Card cages provide support for circuit cards and backplane electrical interconnection, as well as, ease of installation, repair, of circuit cards. In some cases, card cages support 3U Compact PCI (cPCI) systems. Generally, a card cage has an enclosed design to minimizes overall space requirements, but maintains functionality for cooling, EMC, and I/O access. In some cases, the rear section supports signal transition cards and backplane electrical interconnection designed to specific connector requirements.

Generally card cages are cooled by a fan mounted on the bottom with air vents in some or all of the side walls. In some cases the fans may be mounted on one or more surfaces of the card cage to create air cooled systems. In some cases, the card cage also has portions that act as a heat sink/cold plate to cool via conduction.

In certain prior systems the addition of liquid cooling has been used. In prior versions, the heat exchangers are numerous and the plumbing to and from is extensive, prone to leaks, and much harder to build, and assemble. Wherefore it is an object of the present disclosure to overcome the above-mentioned shortcomings and drawbacks associated with the conventional card cages.

### SUMMARY OF THE DISCLOSURE

One aspect of the present disclosure is a liquid cooled card cage, comprising: a top plate and a bottom plate; a single system inlet port and a single system outlet port; and a pair of side walls and at least one center wall; the top plate, the bottom plate, the pair of side walls, and the center wall are configured to form a card cage with at least four slots for accommodating 3U cards; and the card cage being configured such that each plate and each wall is in fluid communication via flow passages and all surfaces of the card cage are useable for cooling.

One embodiment of the liquid cooled card cage is wherein the flow passages are finned. In some cases, the fins of the flow passages are spaced 20 fpi.

Another embodiment of the liquid cooled card cage is wherein at least one external wall of the card cage is configured for mounting non-standard boards and heat sinking the non-standard boards to the external walls. In some cases, the liquid cooled card cage further comprises mass loading spare slots for weight such that a thermal performance of the card cage is sized to account for the spare slots having heat dissipation.

Yet another embodiment of the liquid cooled card cage is wherein orificing at one or more connection points between adjacent plates and walls maintains a pressure drop from the single inlet to the single outlet of no more than 5 psi. In some cases, the card cage does not require any tuning post fabrication. In certain embodiments, the card cage is a compact combination vacuum/dip brazed card cage with integral liquid cooling passages.

Still yet another embodiment of liquid cooled card cage is wherein the single system inlet port and the single system outlet port are both located on the top plate.

Another aspect of the present disclosure is a method of cooling circuit cards, comprising: providing a single inseparable compact combination vacuum/dip brazed card cage having a top plate, a bottom plate, a pair of side walls, and at least on center wall each with integral liquid cooling passages, wherein all surfaces of the card cage are used for cooling; flowing fluid in via a single system inlet port and out via a single system outlet port; flowing fluid from the top plate to a pair of side walls, at least one center wall, and to a bottom plate; and maintaining a pressure drop from the single inlet port to the single outlet port of no more than 5 psi; the card cage being configured to accept at least four 3U circuit cards.

One embodiment of the method of cooling circuit cards is wherein orificing at one or more connection points between adjacent plates and walls regulates system pressure.

Another embodiment of the method of cooling circuit cards further comprises connecting the card cage to test equipment and a chiller to enable subsystem testing prior to assembly into a system.

Yet another embodiment of the method of cooling circuit cards is wherein the liquid cooling passages are finned. In some cases, the fins of the liquid cooling passages are spaced at about 20 fpi.

In certain embodiments, at least one external wall of the card cage is configured for mounting non-standard boards and heat sinking the non-standard boards to the external walls. In certain embodiments, the method of cooling circuit cards further comprises mass loading spare slots for weight such that a thermal performance of the card cage is sized to account for the spare slots having heat dissipation. In some cases, the card cage does not require any tuning post fabrication.

Still yet another embodiment of the method is wherein the single system inlet port and the single system outlet port are both located on the top plate.

Yet another aspect of the present disclosure is a liquid cooled card cage, comprising: a top plate and a bottom plate; a single system inlet port and a single system outlet port; and a pair of side walls and at least one center wall; the top plate, the bottom plate, the pair of side walls, and the center wall are configured to form a card cage with at least four slots for accommodating 3U cards; and the card cage being configured such that each plate and each wall is in fluid communication via flow passages and all surfaces of the card cage are useable for cooling, wherein orificing at one or more connection points between adjacent plates and walls maintains a pressure drop from the single inlet port to the single outlet port of no more than 5 psi.

One embodiment of the liquid cooled card cage is wherein the flow passages are finned. In some cases, the fins of the flow passages are spaced 20 fpi.

Another embodiment of the liquid cooled card cage is wherein at least one external wall of the card cage is configured for mounting non-standard boards and heat sinking the non-standard boards to the external walls.

These aspects of the disclosure are not meant to be exclusive and other features, aspects, and advantages of the present disclosure will be readily apparent to those of ordinary skill in the art when read in conjunction with the following description, appended claims, and accompanying drawings.

### BRIEF DESCRIPTION OF THE DRAWINGS

The patent or application file contains at least one drawing executed in color. Copies of this patent or patent application publication with color drawing(s) will be provided by the Office upon request and payment of the necessary fee. The foregoing and other objects, features, and advantages of the disclosure will be apparent from the following description of particular embodiments of the disclosure, as illustrated in the accompanying drawings in which like reference characters refer to the same parts throughout the different views. The drawings are not necessarily to scale, emphasis instead being placed upon illustrating the principles of the disclosure.

FIG. 1A shows a perspective view of one embodiment of a liquid cooled card cage according to the principles of the present disclosure.

FIG. 1B shows a diagrammatic view of one embodiment of a liquid cooled card cage according to the principles of the present disclosure.

FIG. 2 shows a perspective view of a top plate of one embodiment of a liquid cooled card cage according to the principles of the present disclosure.

FIG. 3A shows a perspective view of a first sidewall of one embodiment of a liquid cooled card cage according to the principles of the present disclosure.

FIG. 3B shows a perspective view of a second sidewall of one embodiment of a liquid cooled card cage according to the principles of the present disclosure.

FIG. 3C shows a perspective view of a third sidewall of one embodiment of a liquid cooled card cage according to the principles of the present disclosure.

FIG. 4 shows a perspective view of a bottom plate of one embodiment of a liquid cooled card cage according to the principles of the present disclosure.

FIG. 5 is a cross-sectional view of one wall of one embodiment of a liquid cooled card cage according to the principles of the present disclosure.

FIG. 6 is a flowchart of one embodiment of a method of liquid cooling a card cage according to the principles of the present disclosure.

### DETAILED DESCRIPTION OF THE DISCLOSURE

One embodiment a liquid cooled card cage according to the principles of the present disclosure provides for reduced packaging complexity for waste heat management of card cage components and support elements (e.g., power supplies) that otherwise might be located elsewhere and require additional coolant lines. In one embodiment, multiple heat exchangers and liquid cooling paths are combined into a single geometry that utilizes all surfaces of the card cage for cooling. This greatly reduces coolant connections, pressure drops, and potential coolant leak points. In some cases, fewer components result in less weight and far less complex liquid cooling plumbing requirements. In certain embodiments, a single inseparable card cage is provided. In certain embodiments, the card cage is an inseparable compact combination vacuum/dip brazed card cage. This approach has application for any liquid cooled designs requiring compact packaging and high heat load dissipation of electronics.

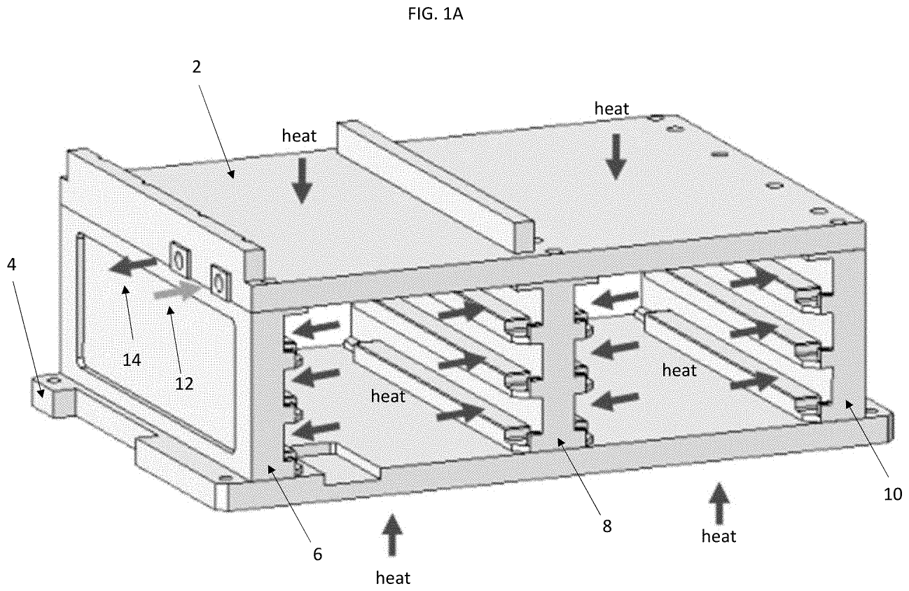

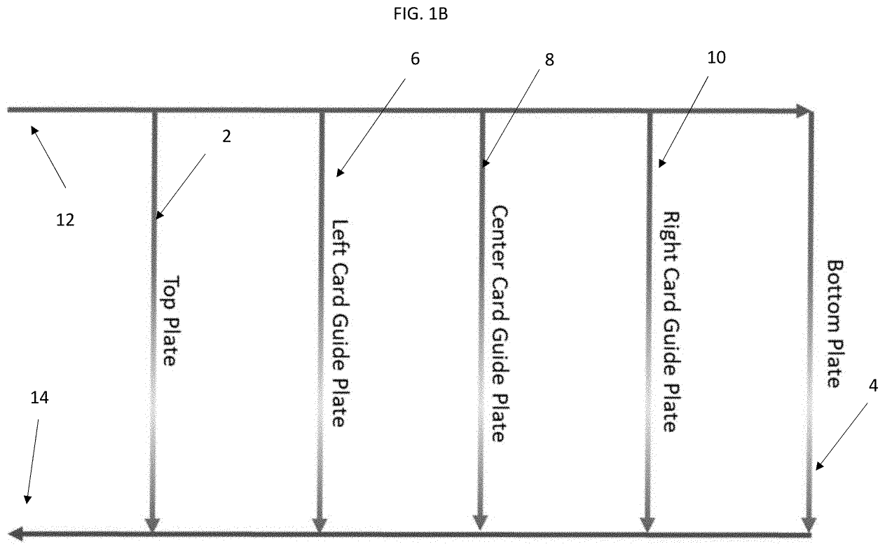

Referring to FIG. 1A, a perspective view of one embodiment of a liquid cooled card cage according to the principles of the present disclosure is shown. More specifically, a compact combination vacuum/dip brazed card cage with integral liquid cooling passages is shown. This card cage allows for cooling standard 3U circuit cards and backplane, in addition to cooling non-standard circuit cards and power supplies attached to the external surfaces of the top and bottom plates of the card cage.

By using vacuum brazed plates, no leaks in the plate can be ensured as well as integrating fin stock, pin fins, flow channels, etc. Then external machining of these plates to mate with each other can be dip brazed or bolted and O-ring sealed to seal plate to plate. At that point, plates may be pinned and aligned such that no machining of the internal card guides after assembly of the card cage would be needed. Also, each plate can be leak checked, pressure tested, pressure drop tested, and tuned.

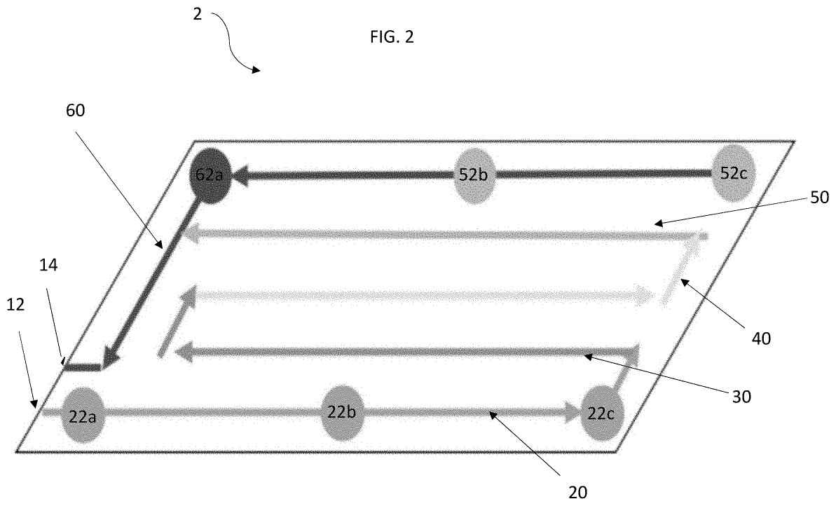

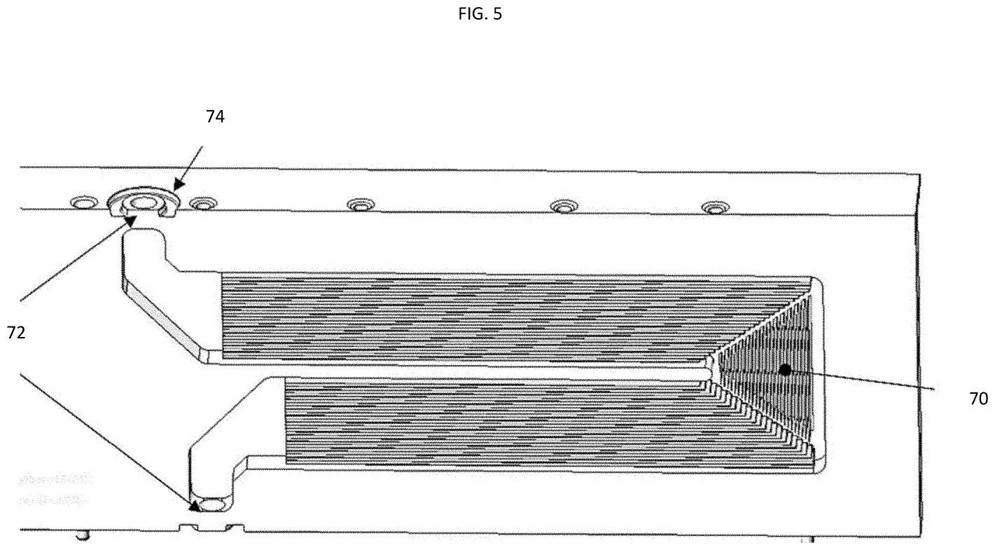

This embodiment shows a card cage having a single fluid inlet port 12 and a single fluid outlet port 14. In this embodiment, both the single fluid inlet port and the single fluid outlet port are located on the top plate. In other embodiments one of the ports may be located on a different plate (e.g., bottom). Internal liquid flow is balanced throughout the entire card cage. Fluid flows through the inlet port 12 in the top plate 2, and out an outlet on each of the card cage walls (6, 8, 10), and then out via the outlet port 14 in the top plate 2 as will be shown in more detail in FIG. 2-FIG. 4. Flow passages in each of the sidewalls and the top and the bottom plates are finned with swept turns for minimizing pressure drops. See, e.g., FIG. 5. In some cases, the sidewalls and the plates are pinned to ensure correct alignment with respect to each other and with respect to the fluid passages on adjoining surfaces. In some embodiments, the fluid may be gas or liquid. In some cases, the fluid is system fluid, e.g., fuel, polyalphaolefin (PAO), olefins, fluorocarbons, and the like.

In one embodiment, the fluid inlet port 12 and the fluid outlet port 14 are NPT threaded into a heat exchanger to accept standard couplers from NPT thread to coolant line tubing. These couplers can have internal orificing for use as a choke of the flow for pressure drop balancing. For systems where multiple heat exchangers are run in parallel, balancing flow is especially important for the proper amount of cooling for the differing thermal loads within the system.

Internal to the heat exchanger depicted, balancing for flow is also needed to ensure each plate receives the proper flow for the thermal load attached to each plate. Plate to plate sealed openings (via O-rings) in this depiction, use orifice washers to balance the flow for this parallel path heat exchanger. As used herein, ports are the system inlet and system outlet for heat exchangers; openings are internal inlets/outlets from plate to plate; and chokes are orifices or reducers that vary in opening size and are used to force more or less flow into a particular plate, parallel path, or whole heat exchanger.

In certain embodiments, 3D printing may be used. However, post machining of long channels that need to be held to tight tolerances would be needed. Additionally, grown materials, specifically Aluminum blends such as AlSiMg, do not have the same thermal conductivity as pure Aluminum such as 6061 or 6063 and may be less favored for certain applications. Lastly, thermal paths are easier to implement with fin stock and flow path geometry as shown in the methods described herein.

In one embodiment, fluid flows into fluid inlet port 12 and splits fluid out to all five of the plates. There are internal paths in the top plate that feed the side plates. The first side plate also passes fluid into the bottom plate. The outlet side of the bottom plate also passes through the first plate back to the top plate. Finally, the top plate outlet path combines fluid from all the plates to exit the fluid outlet port 14. This is depicted in FIGS. 2, 3 and 4.

Still referring to FIG. 1A, a top plate 2 and a bottom plate 4 are joined with at least a first sidewall 6, a center wall 8, and a second side wall 10 to form a card cage. In some cases, the front of the card cage is left open for accepting various cards. The card cage is configured to manage heat from each of the cards within the card cage as well as heat from any components mounted onto the outside surface of the card cage, all while maintaining a continuous, balanced, and compact cooling system.

Referring to FIG. 1B, a diagrammatic view of one embodiment of a liquid cooled card cage according to the principles of the present disclosure is shown. More specifically, a single system inlet port is configured for about a 20-psi max pressure of fluid in the system and the single system outlet port 14 is configured such that no more than a 5 psi drop in pressure as compared to the input pressure is seen. The top plate 2 hosts both the single inlet port 12 and the single outlet port 14 for the card cage in this embodiment. The single inlet port feeds the coolest fluid (blue) into each of the plates/walls of the card cage via inlets (22a, 22b, 22c, 24a). The single outlet port 14 receives the hottest fluid (red) from an outlet in the top plate (62a) and indirectly via outlets (54a, 52b, 52c) in the remaining plates/walls.

Referring to FIG. 2, a perspective view of a top plate of one embodiment of a liquid cooled card cage according to the principles of the present disclosure is shown. More specifically, the top plate 2 hosts both the single inlet port 12 and the single outlet port 14 for the card cage. Fluid enters the single inlet port of the card cage in a first portion 20 of the top plate, where the first portion contains the coolest of the fluid within the card cage system, some of the fluid travels along a first portion path and some of the fluid drops into each of the first sidewall, the center wall, and the second sidewall channels via openings/inlets 22a, 22b, and 22c, respectively. The fluid which traveled along the first portion path 20 enters the second portion path 30, the third portion path 40, the fourth portion path 50, and the fifth portion path 60 where each sequential portion is hotter than the previous portion due to the fluid's absorption of heat as it travels through the system. Within the fourth portion 50, fluid returning from the second sidewall and center wall rejoins the outgoing fluid (via 52b and 52c, respectively) and the first sidewall fluid and bottom plate fluid joins the outgoing fluid in the fifth portion 60 via 62a.

Still referring to FIG. 2, the now heated fluid (red) exits the card cage via the single fluid outlet port 14 where it may be cooled and recirculated into the card cage. In one embodiment, the output of the card cage combines with output of other subsystem heat exchangers, and that flow exits the system to an external environmental control system (ECS) where it is cooled and recirculated back into the system.

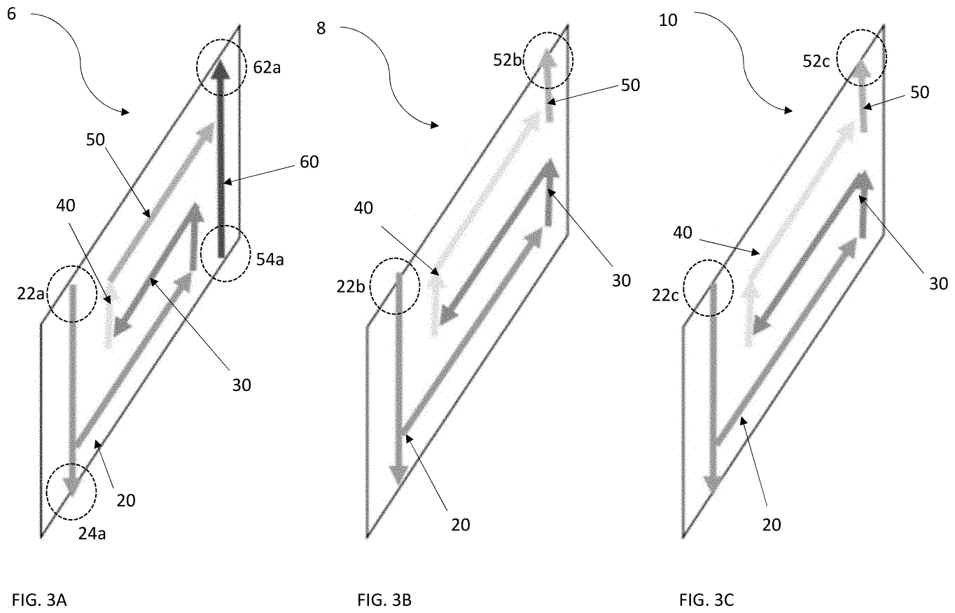

Referring to FIG. 3A, a perspective view of a first sidewall of one embodiment of a liquid cooled card cage according to the principles of the present disclosure is shown. More specifically, fluid enters the first portion 20 of the first sidewall via 22a from the top plate (not shown) and flows through sequential portions (second 30, third 40, fourth 50). The first portion also feeds the coolest fluid (blue) from the top plate (not shown) to the bottom plate (not shown) via 24a. The fourth portion path on the first sidewall 6 joins with fluid returning from the bottom plate (not shown) via the fifth portion 60 and enters the top plate via opening/inlet 62a.

Referring to FIG. 3B, a perspective view of a center wall of one embodiment of a liquid cooled card cage according to the principles of the present disclosure is shown. More specifically, fluid enters the first portion 20 of the center call via 22b from the top plate (not shown) and flows through sequential portions (second 30, third 40, fourth 50). The fourth portion 50 path on the center wall 8 enters the top plate (not shown) via 52b. The middle and end plates do not feed the bottom plate. They are fed from the top and back into the top for the exit.

Referring to FIG. 3C, a perspective view of a second sidewall of one embodiment of a liquid cooled card cage according to the principles of the present disclosure is shown. More specifically, fluid enters the first portion 20 of the second sidewall via 22c from the top plate (not shown) and flows through sequential portions (second 30, third 40, fourth 50). The fourth portion 50 path on the second sidewall 10 enters the top plate (not shown) via 52c.

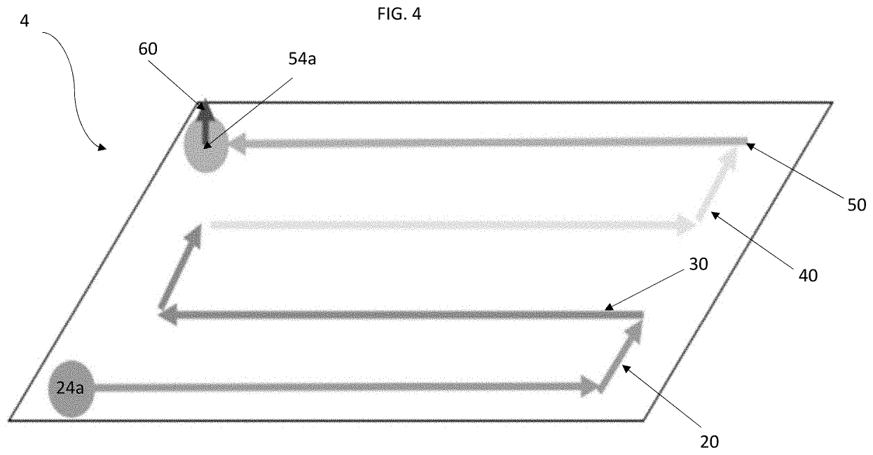

Referring to FIG. 4, a perspective view of a bottom plate of one embodiment of a liquid cooled card cage according to the principles of the present disclosure is shown. More specifically, fluid enters the first portion 20 of the bottom plate via 24a from the top plate, via the first sidewall, and flows through sequential portions (second 30, third 40, fourth 50). The fourth portion 50 path on the bottom plate 4 enters the first sidewall 6 via 54a as it joins with the fifth portion 60 to return to the top plate and exit via the single outlet port of the card cage. In other embodiments, the single outlet port may be located on the bottom or other plate.

In one embodiment, a plurality of cards is combined in card cage (e.g., up to 250 watts) with four other boards (e.g., up to 230 watts) where otherwise these would have been serviced by many separate heat exchangers. This approach combines many of the control electronics into a single sub assembly that is capable of being built and tested separately prior to being integrated into a larger system. In certain embodiments, the system spreads the heat and ensures the boards do not exceed their max board mounting temperatures while occupying a smaller footprint (e.g., less that half a cubic foot) and having fewer heat exchangers and tubing/connections.

Referring to FIG. 5, a cross-sectional view of one wall of one embodiment of a liquid cooled card cage according to the principles of the present disclosure is shown. More specifically, flow passages in each of the sidewalls, the center wall, and in the top and the bottom plates are finned with swept turns for minimizing pressure drops. In some cases, the fins 70 are rectangular fins that are about 0.008″ thick. In some cases, the fins are spaced 20 fins per inch (fpi). In some cases, the flow passages, or channels, are joined to other plates/walls via chokes 72. In some cases, they are sealed via an O-ring set in an O-ring groove 74.

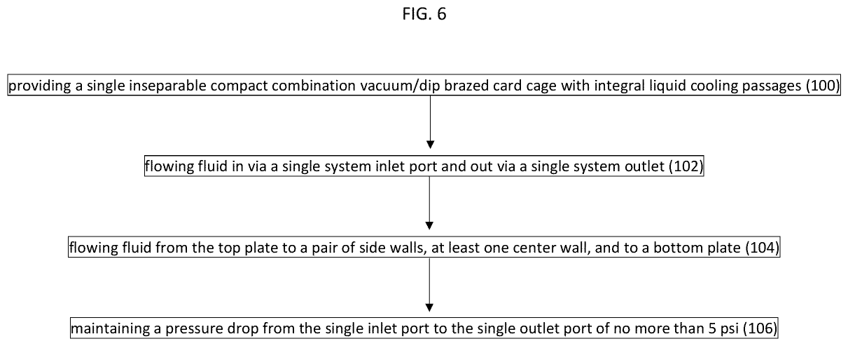

Referring to FIG. 6, a flowchart of one embodiment of a method of liquid cooling a card cage according to the principles of the present disclosure is shown. More specifically, a method of cooling circuit cards provides a single inseparable compact combination vacuum/dip brazed card cage having a top plate, a bottom plate, a pair of sidewalls, and at least on center wall each with integral liquid cooling passages, wherein all surfaces of the card cage are used for cooling 100. Fluid flow is in via a single system inlet port and out via a single system outlet port 102. Fluid flows from the top plate to a pair of side walls, at least one center wall, and to a bottom plate 104; while maintaining a pressure drop from the single inlet port to the single outlet port of no more than 5 psi 106. In some cases, the card cage is configured to accept at least four 3U circuit cards.

In certain embodiments of the card cage of the present disclosure, the card cage brings four or more cooling systems into a single chassis. In some cases, the number of 3U cards in the card cage has room for expansion. That is, a current system only needed 4 of the 6 slots and dummy cards were installed in the two unused slots to maintain mass during testing. Thermal analysis was performed assuming those slots had heat loads so when the system only had four cards, the temperature rise in the card cage was even lower. If the system has six cards installed, the card cage's thermal treatment can still meet system requirements.

While various embodiments of the present invention have been described in detail, it is apparent that various modifications and alterations of those embodiments will occur to and be readily apparent to those skilled in the art. However, it is to be expressly understood that such modifications and alterations are within the scope and spirit of the present invention, as set forth in the appended claims. Further, the invention(s) described herein is capable of other embodiments and of being practiced or of being carried out in various other related ways. In addition, it is to be understood that the phraseology and terminology used herein is for the purpose of description and should not be regarded as limiting. The use of “including,” “comprising,” or “having,” and variations thereof herein, is meant to encompass the items listed thereafter and equivalents thereof as well as additional items while only the terms “consisting of” and “consisting only of” are to be construed in a limitative sense.

The foregoing description of the embodiments of the present disclosure has been presented for the purposes of illustration and description. It is not intended to be exhaustive or to limit the present disclosure to the precise form disclosed. Many modifications and variations are possible in light of this disclosure. It is intended that the scope of the present disclosure be limited not by this detailed description, but rather by the claims appended hereto.

A number of implementations have been described. Nevertheless, it will be understood that various modifications may be made without departing from the scope of the disclosure. Although operations are depicted in the drawings in a particular order, this should not be understood as requiring that such operations be performed in the particular order shown or in sequential order, or that all illustrated operations be performed, to achieve desirable results.

While the principles of the disclosure have been described herein, it is to be understood by those skilled in the art that this description is made only by way of example and not as a limitation as to the scope of the disclosure. Other embodiments are contemplated within the scope of the present disclosure in addition to the exemplary embodiments shown and described herein. Modifications and substitutions by one of ordinary skill in the art are considered to be within the scope of the present disclosure.

What is claimed:

1. A liquid cooled card cage, comprising:
a top plate and a bottom plate;
a single system inlet port and a single system outlet port; and
a pair of side walls and at least one center wall;
the top plate, the bottom plate, the pair of side walls, and the center wall are configured to form a card cage with at least four slots for accommodating 3U cards; and
the card cage being configured such that each plate and each wall is in fluid communication via flow passages and all surfaces of the card cage are useable for cooling.

2. The liquid cooled card cage according to claim 1, wherein the flow passages are finned.

3. The liquid cooled card cage according to claim 2, wherein the fins of the flow passages are spaced 20 fpi.

4. The liquid cooled card cage according to claim 1, wherein at least one external wall of the card cage is configured for mounting non-standard boards and heat sinking the non-standard boards to the external walls.

5. The liquid cooled card cage according to claim 1, further comprising mass loading spare slots for weight such that a thermal performance of the card cage is sized to account for the spare slots having heat dissipation.

6. The liquid cooled card cage according to claim 1, wherein orificing at one or more connection points between adjacent plates and walls maintains a pressure drop from the single inlet to the single outlet of no more than 5 psi.

7. The liquid cooled card cage according to claim 1, wherein the card cage is a compact combination vacuum/dip brazed card cage with integral liquid cooling passages.

8. A method of cooling circuit cards, comprising:
providing a single inseparable compact combination vacuum/dip brazed card cage having a top plate, a bottom plate, a pair of side walls, and at least one center wall all with integral liquid cooling passages, wherein all surfaces of the card cage are used for cooling;
flowing fluid in via a single system inlet port and out via a single system outlet port;
flowing fluid from the top plate to a pair of side walls, at least one center wall, and to a bottom plate; and
maintaining a pressure drop from the single inlet port to the single outlet port of no more than 5 psi;
the card cage being configured to accept at least four 3U circuit cards.

9. The method of cooling circuit cards according to claim 8, wherein orificing at one or more connection points between adjacent plates and walls regulates system pressure.

10. The method of cooling circuit cards according to claim 8, further comprising connecting the card cage to test equipment and a chiller to enable subsystem testing prior to assembly into a system.

11. The method of cooling circuit cards according to claim 8, wherein fins of the liquid cooling passages are spaced at about 20 fpi.

12. The method of cooling circuit cards according to claim 8, wherein at least one external wall of the card cage is configured for mounting non-standard boards and heat sinking the non-standard boards to the external walls.

13. The method of cooling circuit cards according to claim 8, further comprising mass loading spare slots for weight such that a thermal performance of the card cage is sized to account for the spare slots having heat dissipation.

14. The method of cooling circuit cards according to claim 8, wherein the single system inlet port and the single system outlet port are both located on the top plate.

15. The method of cooling circuit cards according to claim 8, wherein the card cage does not require any tuning post fabrication.

16. A liquid cooled card cage, comprising:
a top plate and a bottom plate;
a single system inlet port and a single system outlet port; and
a pair of side walls and at least one center wall;
the top plate, the bottom plate, the pair of side walls, and the center wall are configured to form a card cage with at least four slots for accommodating 3U cards; and
the card cage being configured such that each plate and each wall is in fluid communication via flow passages and all surfaces of the card cage are useable for cooling,
wherein orificing at one or more connection points between adjacent plates and walls maintains a pressure drop from the single inlet port to the single outlet port of no more than 5 psi.

17. The liquid cooled card cage according to claim 16, wherein the flow passages are finned.

18. The liquid cooled card cage according to claim 17, wherein the fins of the flow passages are spaced 20 fpi.

19. The liquid cooled card cage according to claim 16, wherein at least one external wall of the card cage is configured for mounting non-standard boards and heat sinking the non-standard boards to the external walls.

20. The liquid cooled card cage according to claim 16, wherein the single system inlet port and the single system outlet port are both located on the top plate.
